(19) United States
(12) Patent Application Publication
(10) Pub. No.: US 2001/0006151 A1
(43) Pub. Date: Jul. 5, 2001

(54) Method for producing a nickel foam and nickel foam thus obtainable

(76) Inventors: Peter Leerkamp, Boxmeer (NL); Wilhelmus Aloysius Pruyn, Boxmeer (NL)

Correspondence Address: TROUTMAN SANDERS LLP, BANK OF AMERICA PLAZA, SUITE 5200, 600 PEACHTREE STREET , NE, ATLANTA, GA, 30308-2216, US

(21) Appl. No.: 09/748,896

(22) Filed: Dec. 27, 2000

Related U.S. Application Data
(63) Continuation-in-part of application No. PCT/NL99/00400, filed on Jun. 29, 1999.

(30) Foreign Application Priority Data
Jun. 29, 1998 (NL) 1009517

(51) Int. Cl. C25D 1/08; C25D 5/16; C25D 5/08; C23C 14/22

(52) U.S. Cl. 205/75; 205/95; 205/148; 148/518

(57) ABSTRACT

Method for producing a nickel foam having a specific weight of between 200 and 400 g/m², at least comprising the steps of:

providing a base foam having a conductive surface;

nickel-plating the base foam in an electroplating bath, successively in a preplating zone and a main plating zone, whereby in the preplating zone the foam is plated with 0.5-19 g/m² of nickel, whereby retarding means are used to retard the growth of nickel at least during the nucleation phase of the electroplating process, and, in the main plating zone, nickel is plated in the desired amount, such that the ultimate nickel foam has a specific weight of between 200 and 400 g/m², while the flow direction of the electrolyte is reversed and whereby the reversing frequency of the electrolyte in the main plating zone is between 1 mHz and 0.1 Hz, whereby the electroplating bath has a conductivity of at least 200 mS/cm at 20° C.;

finally removing the base foam.

### CROSS-REFERENCE TO RELATED APPLICATIONS

This is a continuation application of PCT/NL 99/00400 filed on Jun. 29, 1999.

### FIELD OF THE INVENTION

The present invention in the first instance relates to a method for producing a nickel foam, comprising the steps of:

providing a base foam having a conductive surface;

nickel-plating the base foam in an electroplating bath;

and removing the base foam.

Such a method is known from the prior art.

### BACKGROUND OF THE INVENTION

The base foam used in practice is often an organic foam material such as polyurethane foam, polyester foam, polystyrene foam or polypropylene foam, although fibre materials made of organic fibres, such as cotton, wool, cellulose etc. or synthetic fibres can also be used. Such organic foam materials need to be made conductive prior to the electroplating, and this can be effected, for example, by using vacuum techniques, such as gas diffusion, cathode sputtering or ion deposition. In this context reference is made to EP-B-0 151 064. Chemical metallization is also possible, however.

Apart from organic foam materials which need to be made conductive, it is also possible to use base foam types already having a conductive surface, such as a conductive plastic foam or a metal foam such as, for example, aluminium foam. In other words, any foam material is suitable as a base foam according to the invention, as long as the base foam, after the metal has been applied, can be removed chemically/physically in some way or other.

Possible ways of removing the base foam are pyrolysis of the base foam, in the case of organic base foams, or with the aid of a solvent. It is also possible for the base foam to be gasified or decomposed under the influence of elevated temperature or radiation.

Until now it has not proved possible to produce metal foam having a low specific weight, yet high tensile strength.

The prior art, for the purpose of producing metal foam having high tensile strength, resorted to the fabrication of a laminate. Usually, metal foam layers were combined with gauze layers or the like. In this context, reference is made to EP-A-0 392 082 where a method of this type is disclosed.

### SUMMARY OF THE INVENTION

It is an object of the present invention to provide a method for producing a metal foam, said foam having a relatively low specific weight and at the same time relatively high tensile strength.

To this end, the present invention provides a method of the type referred to in the introduction, which is characterized in that:

the electroplating is carried out in the electroplating bath, successively in a preplating zone and in a main plating zone;

in the preplating zone, the foam is plated with 0.5-19 g/m² of nickel whereby retarding means are used to retard the growth of nickel at least during the nucleation phase of the electroplating process;

in the main plating zone, nickel is plated in the desired amount, such that the ultimate nickel foam has a specific weight of between 200 and 400 g/m², while the flow direction of the electrolyte is reversed and whereby the reversing frequency of the electrolyte flow direction in the main plating zone is between 1 mHz and 0.1 Hz;

said bath having a conductivity of at least 200 mS/cm at 20°C.

The nickel foam which can be produced by means of the method according to the invention, notwithstanding a relatively low specific weight, has a relatively high tensile strength. Preferably, the specific weight of the ultimate nickel foam is 300 - 350 g/m².

Surprisingly, it was found that if the initial growth of metal (metal nuclei) takes place unusually slowly, the ultimately obtained nickel foam, after removal of the base foam, has a very high tensile strength. Furthermore it proves possible to select a very favourable value, for example very close to one, for the so-called DTR (diameter-thickness ratio), which is a yardstick for the growth thickness of the metal as seen over the thickness of the foam.

To this end, the retarding means are used to retard the growth of nickel at least during the nucleation phase of the electroplating process in the preplating zone.

The retarding means can be selected from many different measures, but preferably are selected from: plating in the preplating zone at a current density which is at most 1/40^{th} of the current density in the main plating zone, or a C-substance in the bath.

The presence of a C-supplying substance further provides the option of preferential growth, in other words, the nickel can be plated in a preferential direction.

This use of a C-supplying substance is known per se. For example, in U.S. Pat. No. 5,584,983 this use is described to obtain a preferential growth of the plating metal.

The C-supplying substance used is advantageously a second-class brightener. Particularly advantageously, the second-class brightener is an olefine or an alkyne, in particular 1,4-butynediol.

During preplating, in particular, at least 0.5 g/m² of nickel is deposited. In practice, about 6 g/m² will be optimal. It is important that not more than 19 g/m² is deposited during the preplating operation.

The current density in the preplating zone is preferably at most 1/40^{th} of the current density in the main plating zone and more preferably at most 1/200^{th} of the current density in the main plating zone.

In the preplating zone, a current of between 5 and 150 A can be chosen, whereas the current in the main plating zone can be chosen between 2000 and 6000 A.

The flow velocity of the electrolyte in the bath is advantageously between 1 and 30 m³/m²/h.

It was found that as a result of the retarding means according to the invention being used, considerably more and also smaller metal nuclei are formed in the bath during the so-called nucleation phase. Likewise, the distribution of the nuclei is better.

In a specific embodiment, the conductivity of the bath is increased. It is found that this results in an even better distribution of the metal nuclei over the base foam and moreover their number increases and their size decreases.

Advantageously the conductivity of the bath is increased by a substance which increases the conductivity being added to the bath. Examples of such conductivity-increasing substances are: alkali metal salts, sulphates/sulphamates of Na, K, Li, Cs, Rb, Mg and NH₄.

Whilst the invention is not particularly limited in terms of the speed at which the base foam is moved through the bath, it is preferable for the rate of movement to be between 5 and 20 m/h.

Although the present description refers to a bath having two plating zones, it is equally possible to make use of two different baths, viz. a preplating bath and a main plating bath.

Finally, the present invention provides a nickel foam which can be obtained by means of the method according to the invention.

Hereinafter the invention will be explained in more detail with reference to an example.

### EXAMPLE

Commercially available types of nickel foam (S1) of various specific weights were compared with types of nickel foam (S2) of corresponding specific weight, which had been produced by means of the method according to the invention. The results are shown in the Table.

TABLE

| | Tensile strength | Tensile strength |
|---|---|---|
| Specific weight | (N/mm) | (N/mm) |
| (g/m²) | S1 | S2 |
| 200 | 0.75 | 1.50 |
| 300 | 1.45 | 2.15 |
| 340 | 1.70 | 2.50 |
| 400 | 2.20 | 2.85 |

The foam thickness used was 1.6 mm, with 67 ppi. The types of nickel foam according to the invention had been prepared under the following conditions: conductivity of the bath 300 mS/cm, reversal frequency of electrolyte flow direction 8 mHz, a flow velocity of the electrolyte of 20 m³/m²/h, 40 mg/l of 1,4-dibutynediol in the bath, and preplating of a polyurethane foam with 15 g/m² of nickel. After plating, the polyurethane foam was removed by pyrolysis and the nickel foam was annealed.

### BRIEF DESCRIPTION OF THE DRAWINGS

In the accompanying drawing,

FIG. 1 shows a photograph made using a scanning electron microscope of nickel nuclei on a foam just after the nucleation phase in an electroplating bath with 1,4-butynediol as a second-class brightener; and

FIG. 2 shows a photograph made using a scanning electron microscope of nickel nuclei on a foam just after the nucleation phase in an electroplating bath according to the prior art without retarding means.

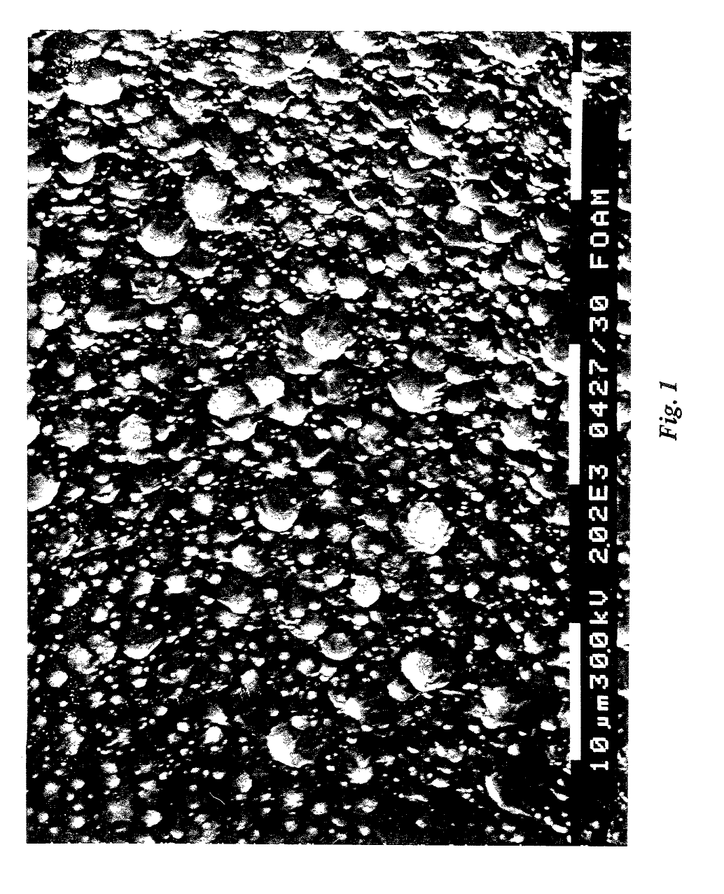

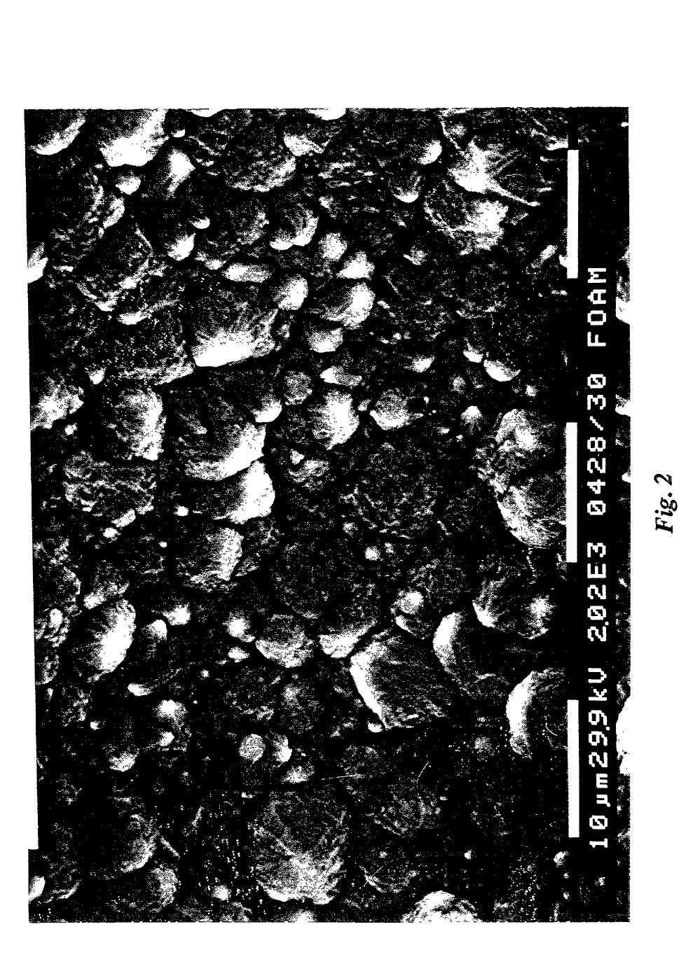

A comparison of the photographs from FIGS. 1 and 2 clearly shows that if retarding means according to the invention are used in an electroplating bath during the nucleation phase, considerably more smaller and better-distributed nickel nuclei are obtained on the surface of the base foam.

What is claimed is:

1. Method for producing a nickel foam, comprising the steps of:
providing a base foam having a conductive surface;
nickel-plating the base foam in an electroplating bath;
and removing the base foam, wherein:
the electroplating is carried out in the electroplating bath, successively in a preplating zone and in a main plating zone;
the foam is plated with 0.5-19 g/m² of nickel, whereby retarding means are used to retard the growth of nickel at least during the nucleation phase of the electroplating process;
in the main plating zone, nickel is plated in the desired amount, such that the ultimate nickel foam has a specific weight of between 200 and 400 g/m², while the flow direction of the electrolyte is reversed and whereby the reversing frequency of the electrolyte flow direction in the main plating zone is between 1 mHz and 0.1 Hz.
said bath having a conductivity of at least 200 mS/cm at 20°C.

2. Method according to claim 1, wherein the retarding means are selected from:
plating in the preplating zone at a current density which is at most 1/40^{th} of the current density in the main plating zone;
a C-supplying substance in the bath.

3. Method according to claim 1 or 2, wherein the conductivity of the bath is increased.

4. Method according to claim 3, wherein the conductivity of the bath is increased by a substance which increases the conductivity being added to the bath.

5. Nickel foam which is obtainable by means of the method according to one or more of the preceding claims.
